(19) United States
(12) Patent Application Publication
(10) Pub. No.: US 2005/0201495 A1
(43) Pub. Date: Sep. 15, 2005

(54) Reproducing apparatus and method for controlling the same

(75) Inventors: Tomoko Sogabe, Kyoto (JP); Takeshi Fujita, Osaka (JP); Futoshi Shirakihara, Kyoto (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/057,758

(22) Filed: Feb. 15, 2005

(30) Foreign Application Priority Data
Mar. 10, 2004 (JP) 2004-066946

(51) Int. Cl. H03D 1/00; H04L 27/06

(52) U.S. Cl. 375/340; 375/365

(57) ABSTRACT

A synchronization signal detecting section is internally provided with a stream type counter for counting stream type information output from a header information analyzer and a stream type determining section for instructing, based on a value in the stream type counter, a signal processing section to initiate stream conversion. If the value in the stream type counter reaches a predetermined value, it is determined that the input signal is a stream signal. If the value in the stream type counter does not reach the predetermined value, synchronization signal detection is restarted from the address which is one bit ahead of an address stored in a synchronization address storing section.

### CROSS-REFERENCE TO RELATED APPLICATION

The disclosure of Japanese Patent Application No. 2004-66946 filed on Mar. 10, 2004 including specification, drawings and claims is incorporated herein by reference in its entirety.

### BACKGROUND OF THE INVENTION

The present invention relates to reproducing apparatuses for reproducing media such as CDs on which digital audio signals are recorded, and methods for controlling the apparatuses, and more particularly relates to reproduction of PCM digital audio signals and reproduction of stream signals compression-coded at variable-length bit rates.

Conventionally, whether a digital audio signal recorded on a medium such as a CD is a PCM digital audio signal or an audio signal encoded at given bit rates and having therein synchronization signals at those bit rates (which will be hereinafter referred to as a “stream signal”) has been determined by examining periodicity in which the synchronization signals detected from the digital audio signal appear during decoding of the digital audio signal, and processing for preventing malfunction is performed frame by frame. However, in this process, the determination as to whether the digital audio signal is a stream signal or a PCM digital audio signal cannot be made without actually decoding the digital audio signal, which may cause noise to occur.

In order to overcome the above problem, it has been known that if the determination of whether or not the audio signal is a stream signal is made with a certain degree of reliability prior to the decoding process, the possibility of occurrence of noise during the decoding process can be reduced (see Japanese Laid-Open Publication No. 2002-190156.)

Hereinafter, referring to FIGS. 1 through 5, the conventional technique will be described by taking an audio signal in MP3 format as an example. An input signal input to a reproducing apparatus is either a PCM digital audio signal or a stream signal which is compression-coded at given bit rates and in which synchronization signals are recorded at intervals defined by those bit rates. Each bit rate is contained in header frame information succeeding a corresponding one of the synchronization signals. Each synchronization signal indicates the beginning of a frame which is a unit for processing.

FIG. 1 illustrates an MP3-format stream configuration. A frame 1 includes a 12-bit synchronization signal 2, a 20-bit header frame 3 succeeding the synchronization signal 2, and a subframe 4. In the case of MP3, the synchronization signal 2 has a value of “0xfff”.

The header frame 3 contains information indicating frame states, such as a bit rate which determines the frame length, the kind and type of frame, a sampling frequency, and information on an emphasis. In the case of MP3, the value of a bit rate ranges from “0x0” to “0x0f”. When the value of a bit rate is “0x00” or “0x0f”, the bit rate is indeterminate.

FIG. 2 indicates the configuration of, and the flow of processing in, an MP3 reproducing apparatus. An input signal (an MP3 stream signal) is input to the reproducing apparatus through a signal input section 10. The input signal is then input to a synchronization signal detecting section 11.

FIG. 3 illustrates the configuration of the synchronization signal detecting section 11. In the synchronization signal detecting section 11, the input signal 28 is input bit by bit to a data counter 20 and a synchronization signal detector 21. The data counter 20 counts the number of bits of the input signal, while the synchronization signal detector 21 detects a synchronization signal from the input signal 28. Although the number of bits to be input is arbitrary and varies depending upon the system, processing is performed bit by bit in this description.

The synchronization signal detector 21 compares the last 12-bit data including the currently input data with a synchronization signal, thereby detecting a synchronization signal from the input signal. In this description, the synchronization signal compared has a value of “0xfff”. Also, the comparison range, which may be any range depending on the system, is 2 Kbyte in this description.

Upon the detection of the first synchronization signal, the synchronization signal detector 21 sends address information on the first data in the synchronization signal to a first synchronization address storing section 23 by way of the data counter 20, while setting a synchronization counter storing section 26 to 0, The synchronization signal detector 21 also inputs header information succeeding the synchronization signal to a header information analyzer 22.

The header information analyzer 22 analyzes bit rate information in the input header information. When the analyzed bit rate is not indeterminate, the header information analyzer 22 calculates an interval to a subsequent synchronization signal and stores the address of the subsequent synchronization signal in a subsequent synchronization signal address storing section 25. When the bit rate is indeterminate, it is determined that the signal, having the value “0xfff”, detected by the synchronization signal detector 21 is not a synchronization signal, and the synchronization signal detection process is restarted from the address which is a given value ahead of the address stored in the first synchronization address storing section 23. In this description, as shown in FIG. 4A, the synchronization signal detection is restarted from the address which is one bit ahead.

When the value of the data counter 20 matches to the value of the subsequent synchronization signal address storing section 25, a subsequent synchronization signal comparison start determining section 24 outputs determination of the start of the synchronization signal detection to the synchronization signal detector 21.

If the input signal is a synchronization signal, the synchronization signal detector 21 increments a synchronization counter and sets the incremented value in the synchronization counter storing section 26. If the input signal is not a synchronization signal, the synchronization signal detection is restarted from the address which is one bit ahead of the address stored in the first synchronization address storing section 23, as in the case where the bit rate is indeterminate.

As shown in FIG. 4B, when the value of the synchronization signal counter reaches a predetermined value within a synchronization signal search area, it is determined that the input signal is a stream signal. On the other hand, when the input data exceeds the synchronization signal search area, the input signal is determined to be a PCM digital audio signal. In this description, the predetermined value is 256.

Then, output information for determining output in accordance with the determined type of the input signal is sent to a determination output section 27.

FIG. 5 indicates the flow of processing in the synchronization signal detecting section 11 shown in FIG. 3. The synchronization signal detecting section 11 performs steps S401 through S420.

In a step S401, it is determined whether or not there is any synchronization signal within a predetermined search area. The determination is made by the following operation, for example.

If the determination made in the step S401 is “No”, it is determined that the input signal input to the reproducing apparatus is a PCM signal (in a step S402), and the determination operation is ended.

If “Yes” in the step S401 is, the operation branches to a step S403. In the step S403, it is determined whether or not the input data input to the synchronization signal detector 21 is a synchronization signal.

If the determination made in the step S403 is “Yes”, the process proceeds to a step S404, and the address of the first synchronization signal provided from the data counter 20 is stored in the first synchronization address storing section 23.

If “No” in the step S403, the process branches to a step S405, in which the data counter 20 is incremented and the synchronization signal detection is restarted from the address which is one bit ahead of an address stored in the first synchronization address storing section 23.

In a step S406, the synchronization counter storing section 26 is set to 0. Then, in a step S407, the header information analyzer 22 analyzes header information succeeding the synchronization signal to calculate a bit rate.

Next, in a step S408, the header information analyzer 22 makes a determination, based on the result of the frame header analysis, as to whether or not the bit rate has a value indicating that the bit rate is indeterminate. When the value of the bit rate is “0x00” or “0x0f”, it is determined that the bit rate is indeterminate.

If the determination made in the step S408 is “Yes”, the operation of the synchronization signal detecting section 11 branches to a step S412. If “No” in the step S408, the operation of the synchronization signal detecting section 11 branches to a step S409.

In the step S409, the header information analyzer 22 calculates an interval to a subsequent synchronization signal based on the header information. And in a step S410, the header information analyzer 22 skips reading of a portion of the input data between the first synchronization signal position and the subsequent synchronization signal position and stores the address of the subsequent synchronization signal position in the subsequent synchronization signal address storing section 25.

In a step S411, whether or not data present in the subsequent synchronization signal position is a synchronization signal is determined. If the determination is “No”, the process branches to the step S412, and if “Yes”, the process branches to a step S413.

In the step S412, based on the determination that the signal, having the value “0xff”, detected by the synchronization signal detector 21 and presumed to be a synchronization signal is not a synchronization signal, the synchronization signal detection is restarted from the address which is a given bit ahead of the address stored in the first synchronization address storing section 23.

In the step S413, the synchronization counter storing section 26 is incremented, and in a step S414, the subsequent synchronization signal comparison start determining section 24 determines whether or not the value of the data counter 20 is equal to the value of the subsequent synchronization signal address storing section 25.

When the determination made in the step S414 is “Yes”, it is determined that the input signal input to the reproducing apparatus is a stream signal (in a step S415) and the determination operation is ended.

When “No” in the step S414, the operation branches to a step S416. In the step S416, the header information analyzer 22 analyzes header information following the synchronization signal, thereby calculating a bit rate.

Next, in a step S417, the header information analyzer 22 makes a determination, based on the result of the frame header analysis, as to whether or not the bit rate has a value indicating that the bit rate is indeterminate. When the value of the bit rate is “0x00” or “0x0f”, it is determined that the bit rate is indeterminate.

If the determination made in the step S417 is “Yes”, the operation of the synchronization signal detecting section 11 branches to the step S412. If “No” in the step S417, the operation of the synchronization signal detecting section 11 branches to a step S418.

In the step S418, the header information analyzer 22 calculates an interval to a subsequent synchronization signal based on the header information. In a step S419, the header information analyzer 22 skips reading of a portion of the input data between the first synchronization signal position and the subsequent synchronization signal position and stores the address of the subsequent synchronization signal position in the subsequent synchronization signal address storing section 25.

In a step S420, it is determined whether or not data present in the subsequent synchronization signal position is a synchronization signal. If the determination is “No”, the process branches to the step S412, and if “Yes”, the process branches to the step S413.

As a result of the above operation, if it is determined that the input signal is a stream signal, the signal input section 10 inputs, to a signal processing section 12, data in the address stored in the first synchronization address storing section 23 in the synchronization signal detecting section 11, while the synchronization signal detecting section 11 inputs to the signal processing section 12 output information corresponding to the determined type of the input signal. In the signal processing section 12, a decoding process corresponding to the type of the stream signal is performed based on the output information, and an output adjusting section 13 controls and outputs a gain.

### SUMMARY OF THE INVENTION

In the above-mentioned conventional example, reliability at the time that decoding process is started is increased to reduce occurrence of noise significantly, but it is not possible to eliminate the possibility of occurrence of noise during the decoding process. In addition, in cases where the reliability of an input signal recorded on a CD is low due to, e.g., a scratch on the disc, the signal may not be reproduced, or even if the reproduction can be started, synchronization signals may not be detected correctly, causing noise to occur. Also, in the case of a reproducing apparatus having the signal processing function of decoding a plurality of types of streams, the frequency of detection of false synchronization signals is increased, producing noise more frequently.

In view of this, the present invention was made and an object thereof is to minimize occurrence of noise caused by false synchronization signals in reproducing a stream signal which is compression-coded at given bit rates including variable-length bit rates.

To achieve the above object, in an input signal which is being decoded, features of stream information which accompanies a synchronization signal in the stream signal are stored and compared with features of stream information accompanying a subsequent synchronization signal. If the comparison result shows that a certain condition is satisfied, it is determined that the signal is a stream and is then decoded, thereby reducing occurrence of noise.

An inventive reproducing apparatus includes: a signal input section for receiving an input signal containing a PCM digital audio signal or a stream signal which is compression-coded at given bit rates and in which synchronization signals and frame headers are recorded at intervals defined by the bit rates, each synchronization signal indicating the beginning of a frame which is a unit for processing, each frame header indicating information on a corresponding one of the bit rates; a synchronization signal detecting section for detecting the synchronization signals in the input signal, thereby determining a type of the input signal; a host controller for setting an operation condition for the synchronization signal detecting section in accordance with the type of the input signal, and outputting output information which determines output; a signal processing section for subjecting the input signal a signal processing process according to the output information; and an output adjusting section for outputting data resulting from the signal processing process performed by the signal processing section.

The inventive reproducing apparatuses receive an input signal containing a PCM digital audio signal or a stream signal which is compression-coded at given bit rates and in which synchronization signals, each indicating the beginning of a frame which is a unit for processing, and frame headers, each indicating information on a corresponding one of the bit rates, are recorded at intervals defined by the bit rates. In the inventive reproducing apparatuses and in the inventive methods for controlling the apparatuses, occurrence of noise caused by false synchronization signals is reduced by associating a synchronization signal in a stream signal which is expected to be input and part of header information succeeding the synchronization signal with a subsequent synchronization signal and part of header information succeeding the subsequent synchronization signal.

### BRIEF DESCRIPTION OF THE DRAWINGS

FIG. 1 illustrates the configuration of an exemplary conventional stream signal.

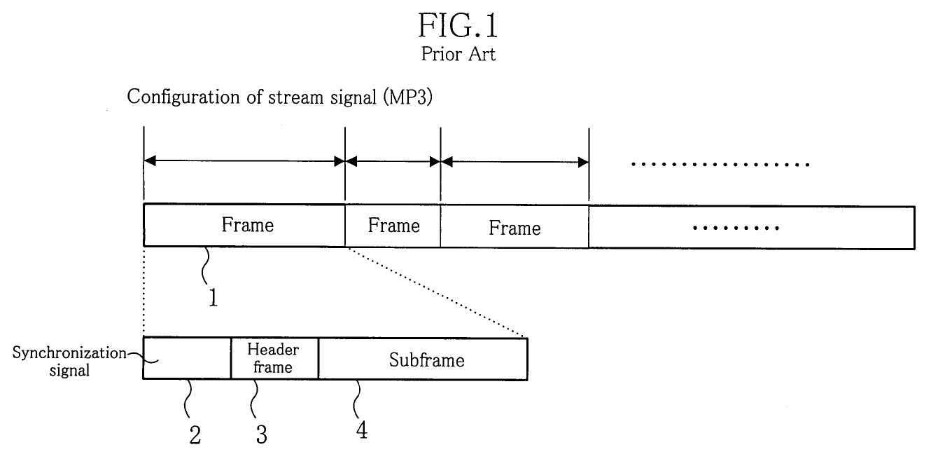

FIG. 2 illustrates a conventional reproducing apparatus.

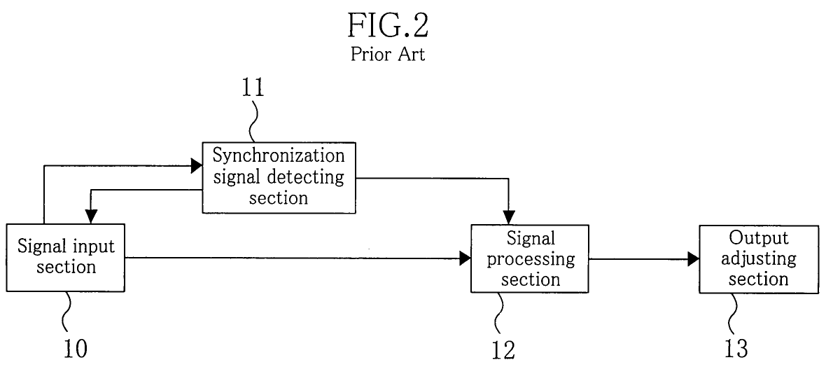

FIG. 3 illustrates the configuration of a conventional synchronization signal detecting section.

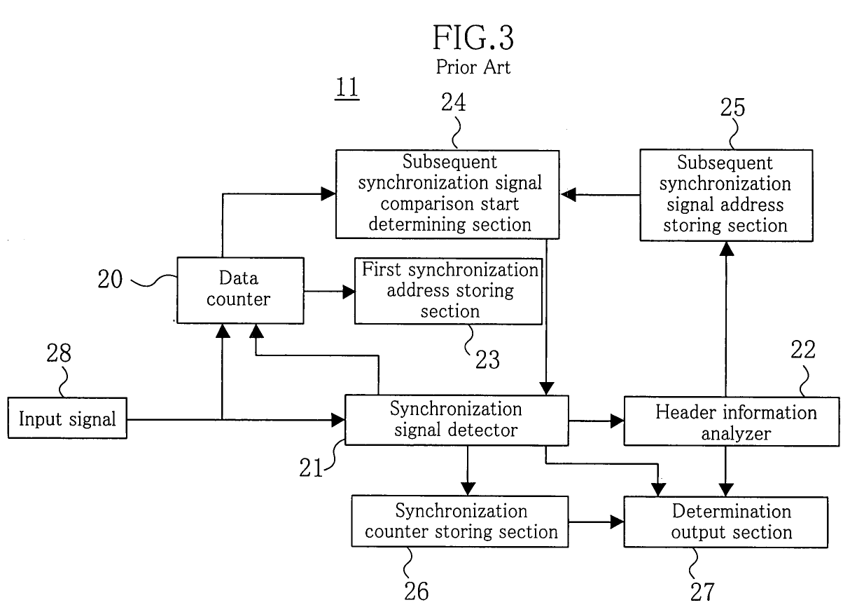

FIG. 4 indicates a conventional synchronization signal detection method.

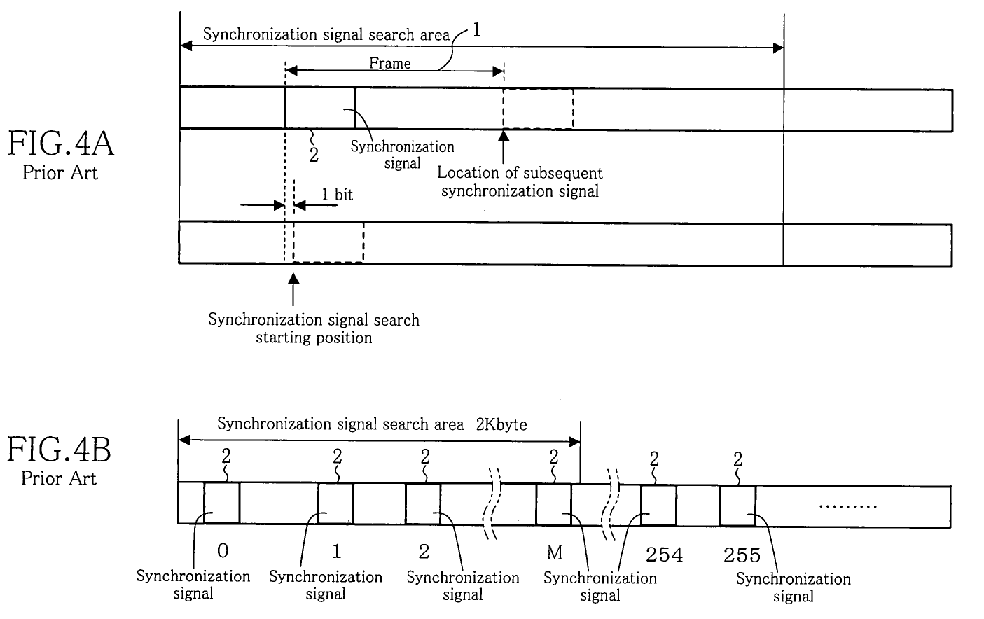

FIG. 5 indicates the flow of processing in the conventional synchronization signal detecting section.

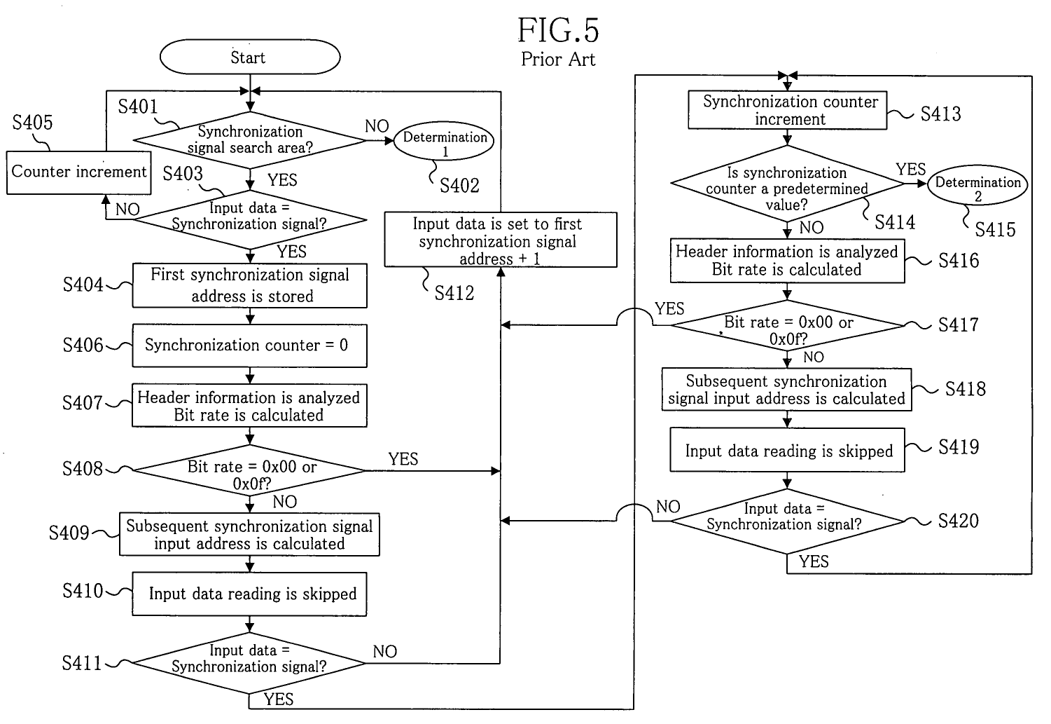

FIG. 6 illustrates the configuration of a reproducing apparatus according to a first embodiment of the present invention.

FIG. 7 illustrates the configuration of a synchronization signal detecting section according to the first embodiment of the present invention.

FIG. 8 indicates the flow of processing in the synchronization signal detecting section according to the first embodiment of the present invention.

FIG. 9 illustrates the configuration of header information according to the first embodiment of the present invention.

FIG. 10 indicates a header information determination method according to the first embodiment of the present invention.

FIG. 11 indicates an exemplary input signal about which determination is likely to be made erroneously.

FIG. 12 illustrates the configuration of a reproducing apparatus according to a second embodiment of the present invention.

FIG. 13 illustrates the configuration of a synchronization signal detecting section according to the second embodiment of the present invention.

FIG. 14 indicates a sampling frequency information determination method according to the second embodiment of the present invention.

FIG. 15 illustrates the configuration of a reproducing apparatus according to a third embodiment of the present invention.

FIG. 16 illustrates the configuration of a synchronization signal detecting section according to the third embodiment of the present invention.

FIG. 17 indicates a stream type information determination method according to the third embodiment of the present invention.

FIG. 18 illustrates the configuration of a reproducing apparatus according to a fourth embodiment of the present invention.

FIG. 19 indicates a determination method performed by a host controller according to the fourth embodiment of the present invention.

### DESCRIPTION OF THE PREFERRED EMBODIMENTS

Hereinafter, preferred embodiments of the present invention will be described in detail with reference to the accompanying drawings. It should be noted that the following preferred embodiments are essentially illustrative only and are not intended to limit the present invention, the scope of application of the invention, and the manner of applying the invention.

### First Embodiment

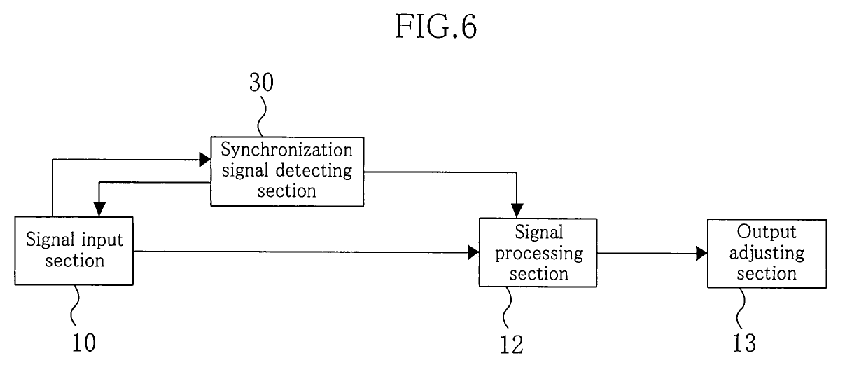

A reproducing apparatus according to a first embodiment of the present invention will be described with reference to FIGS. 6 through 11. An input signal input to the reproducing apparatus is a PCM digital audio signal or a stream signal which is compression-coded at given bit rates and in which synchronization signals and frame headers are recorded at intervals defined by the bit rates. Each synchronization signal indicates the beginning of a frame which is a unit for processing, while each frame header indicates information on a corresponding one of the bit rates.

To describe the first embodiment with specific figures, it is assumed that, as in the above conventional example, the stream signal is in MP 3 format, which is one type of encoding method.

Description of the MP3 stream configuration, which is the same as that in the conventional example, will thus be omitted herein. In the case of MP3, the value of a bit rate ranges from “0x00” to “0x0f”. In the first embodiment, when a bit rate has a value of “0x00” or “0x0f”, the bit rate is considered to be indeterminate.

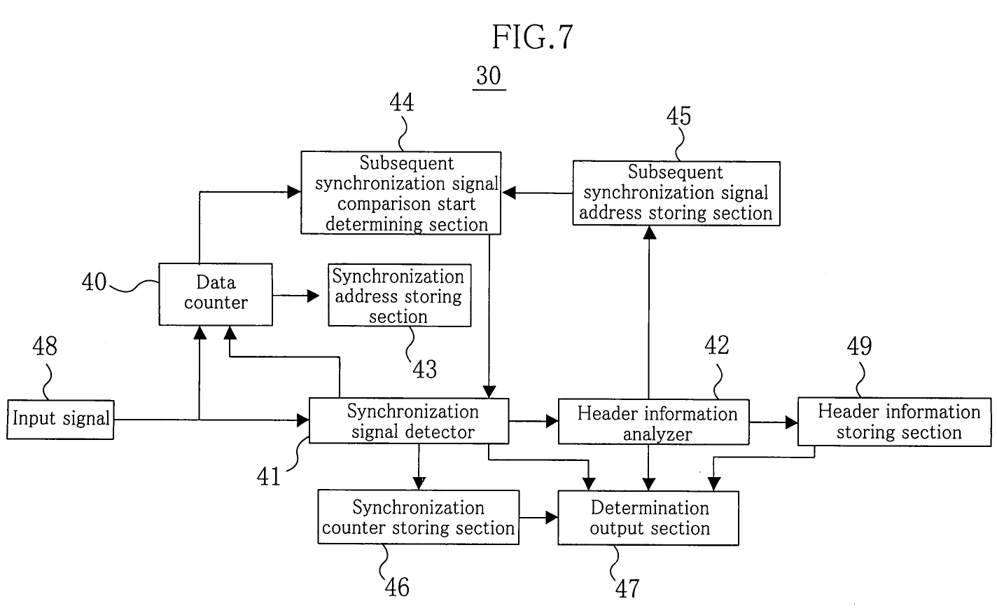

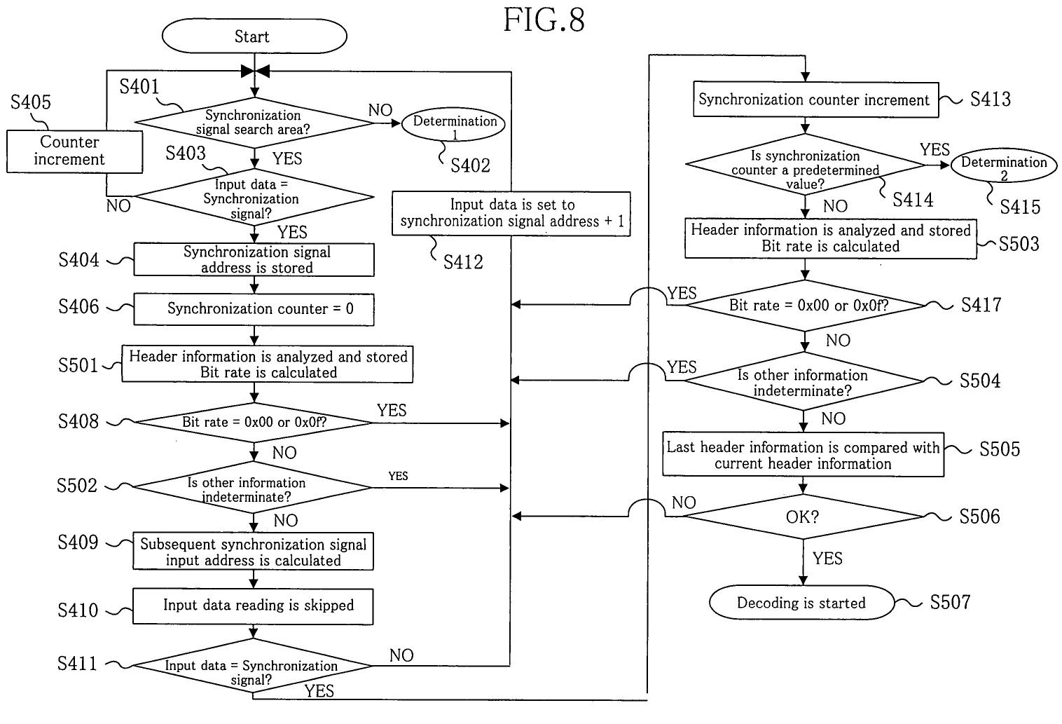

FIG. 6 illustrates the configuration of the MP3 reproducing apparatus. The basic configuration of the reproducing apparatus is the same as that of the conventional example and description thereof will thus be omitted herein. FIG. 7 illustrates the configuration of a synchronization signal detecting section 30, while FIG. 8 indicates the flow of processing in the synchronization signal detecting section 30. Since synchronization signals are detected in the same manner as in the conventional example, description of the synchronization signal detection method will thus be omitted herein.

A header information analyzer 42 analyzes bit rate information in input header information and also stores in a header information storing section 49 all information contained in the header information but the analyzed bit rate information.

Specifically, as shown in FIG. 8, in a step S501, the header information analyzer 42 analyzes header information succeeding a synchronization signal to calculate a bit rate, while storing in the header information storing section 49 all information contained in the header information but the bit rate. If it is determined that the bit rate in the header information in the input signal is not indeterminate in a step S408, whether or not the other information stored in the header information storing section 49 is indeterminate is determined in a step S502.

If the determination made in the step S502 is “Yes”, the operation of the synchronization signal detecting section 30 branches to a step S412. If “No” in the step S502, the operation of the synchronization signal detecting section 30 branches to a step S409.

Then, a subsequent synchronization signal is detected in the same manner as in the conventional example, and when a determination made in a step S414 is “No”, the operation branches to a step S503. In the step S503, the header information analyzer 42 analyzes header information succeeding the synchronization signal to calculate a bit rate, while storing the other information in the header information storing section 49.

Next, in a step S417, the header information analyzer 42 determines, based on the frame header analysis result, whether or not the bit rate has a value indicating that the bit rate is indeterminate. When the value of the bit rate is “0x00” or “0x0f”, it is determined that the bit rate is indeterminate.

If the determination made in the step S417 is “Yes”, the operation of the synchronization signal detecting section 30 branches to the step S412. If “No” in the step S417, the operation of the synchronization signal detecting section 30 branches to a step S504.

In the step S504, it is determined whether or not the other information stored in the header information storing section 49 is indeterminate.

If the determination made in the step S504 is “Yes”, the operation of the synchronization signal detecting section 30 branches to a step S505. If “No” in the step S504, the operation of the synchronization signal detecting section 30 branches to the step S412.

In the step S505, the first header information is compared with the subsequent header information, and the comparison result is examined in a step S506. If the comparison result indicates “OK” (which means that the first header information and the subsequent header information match with each other) in the step S506, decoding of the input signal is started in a step S507. If it is determined that the comparison result is “No” (which means that the first header information and the subsequent header information do not match with each other) in the step S506, the operation branches to the step S412 and the synchronization signal detection is performed again.

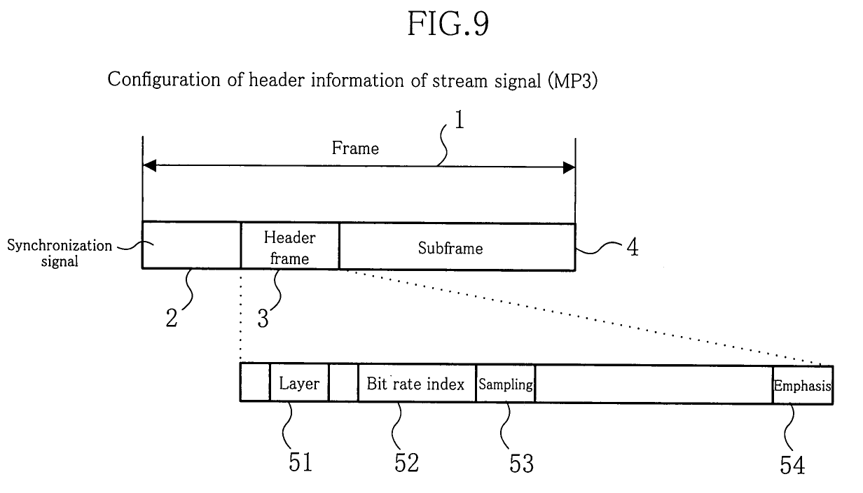

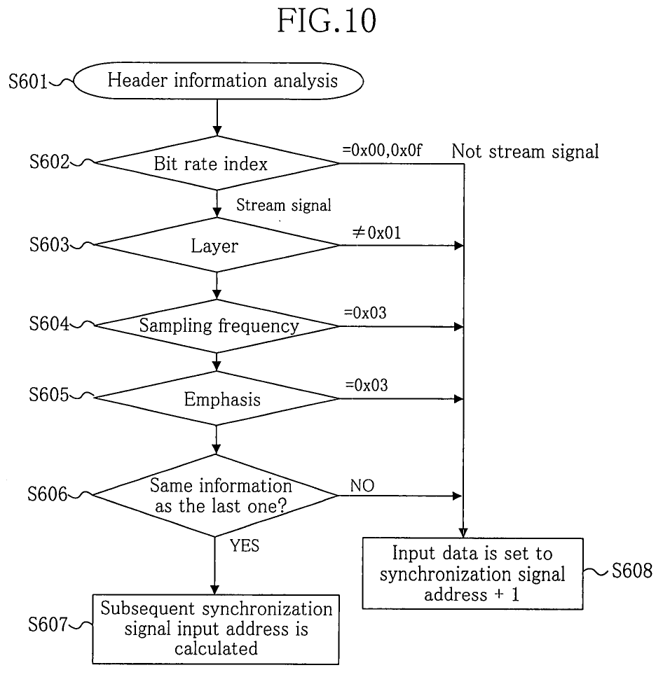

FIG. 9 illustrates the configuration of the other header information, while the FIG. 10 indicates the flow of the header information analysis determination. Each MP3 header information contains not only a bit rate index 52 indicating an interval between the corresponding synchronization signals, but also information, such ash a layer 51, a sampling frequency 53, and an emphasis 54, which indicates that the stream signal is a MP3 stream. By adding determinations about these sets of information, it is possible to increase the chance of determining that the input synchronization signal is not a false synchronization signal.

As shown in FIG. 10, in a step S601, the header information analyzer 42 analyzes input header information to calculate the values of the bit rate index 52, layer 51, sampling frequency 53, and emphasis 54.

In a step S602, if the bit rate index 52 has a value of “0x00” or “0x0f” indicating that the bit rate index is indeterminate, it is determined that the input signal is not a stream signal, and the process branches to a step S608. If the bit rate index 52 has a value other than “0x00” and “0x0f”, the process branches to a step S603.

In the step S603, if the layer 51 has a value of “0x01”, it is determined that the input signal is not a stream signal and the process branches to the step S608. If the layer 51 has a value other than “0x01”, the process branches to a step S604.

In the step S604, if the sampling frequency 53 has a value of “0x03”, it is determined that the input signal is not a stream signal and the process branches to the step S608. If the sampling frequency 53 has a value other than “0x03”, the process branches to a step S605.

In the step S605, if the emphasis 54 has a value of “0x03”, it is determined that the input signal is not a stream signal and the process branches to the step S608. If the emphasis 54 has a value other than “0x03”, the process branches to a step S606.

In the step S606, it is determined whether or not the header information is the same as the last header information. If the determination made is “Yes”, the process branches to a step S607, in which a subsequent synchronization signal input address is calculated.

If the determination made in the step S606 is “No”, the process branches to the step S608, in which, based on the determination that the value “0xfff” detected by the synchronization signal detecting section 41 and assumed to be a synchronization signal is not a synchronization signal, the synchronization signal detection is restarted from the address which is one bit ahead of the address stored in the synchronization address storing section 43.

By the above operation, it is possible to increase the chance of determining that the synchronization signal detected from the input signal is not a false synchronization signal, thereby suppressing occurrence of noise.

Although in this embodiment the determination process is performed for all of the information contained in the header information, the range of determination may be changed according to the throughput and hard resources of the system that performs the determination process.

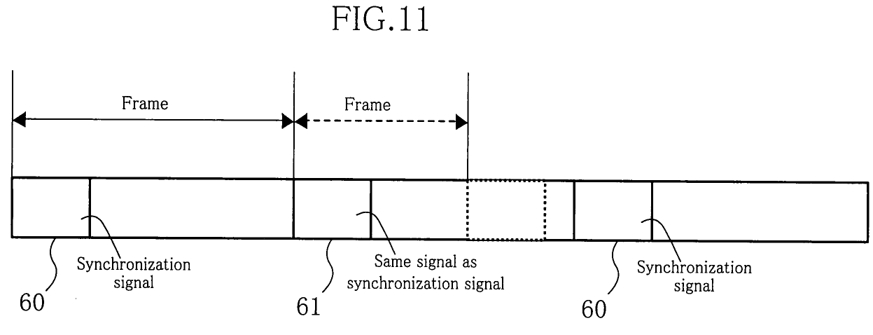

Next, among actual input signals, a signal on which determination is likely to be erroneously made is given as an example to explain the effectiveness of the reproducing apparatus control method of the first embodiment. FIG. 11 indicates an exemplary input signal on which determination is likely to be made erroneously. The exemplary stream signal contains signals (false synchronization signals) 61 which are the same as synchronization signals 60. In the case of this signal, if the synchronization signals are detected at intervals defined by the bit rates in the header information, there is a high probability that noise will occur.

However, even if a synchronization signal has been detected, the last header information and the current header information are compared in the step S505, and the comparison result is examined in the step S506. If the comparison result is “OK” (which means that the last header information and the current header information match with each other) in the step S506, decoding is started in the step S507. If the comparison result is “No” (which means that the last header information and the current header information do not match with each other) in the step S506, the process branches to the step S412 so that the synchronization signal detection is performed again, whereby it is possible to determine that the signal is a false synchronization signal, thereby preventing occurrence of noise.

In this manner, it is possible to configure the reproducing apparatus in which occurrence of noise is reduced by analyzing not only the header information succeeding the current synchronization signal but also the header information succeeding the subsequent synchronization signal.

### Second Embodiment

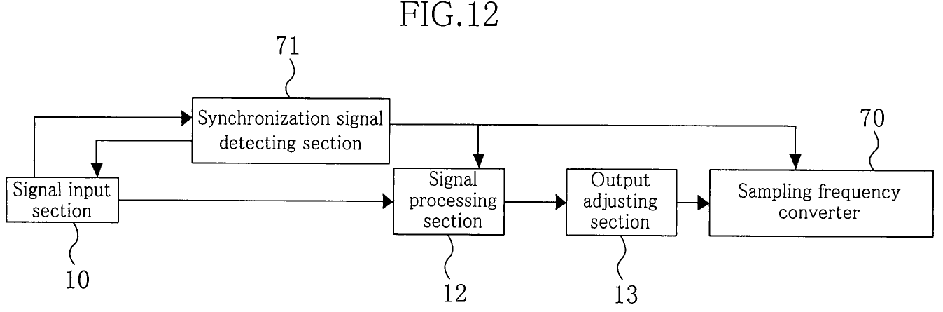

A second embodiment of the present invention will be described with reference to FIGS. 12 through 14. The configuration of, and the flow of processing in, a reproducing apparatus according to the second embodiment are basically the same as those of the first embodiment. The second embodiment will thus be described only in terms of its differences from the first embodiment.

As shown in FIG. 12, the reproducing apparatus is configured by incorporating a sampling frequency converter 70 in the reproducing apparatus of the first embodiment.

The sampling frequency converter 70 converts an output signal produced from an output adjusting section 13 to a predetermined sampling frequency. From sampling frequency information contained in the stream signal, the frequency to be sampled is determined. In the reproducing apparatus with this configuration, if a malfunction occurs due to a false synchronization signal and false sampling frequency information succeeding the false synchronization signal to cause switching to take place frequently, noise may be produced.

In the first embodiment, the frames in the stream signal except for the frames whose sampling frequency is indeterminate are reproduced, such that a false-synchronization-signal induced malfunction may cause noise to occur. Also, in cases where the header information in the first synchronization signal is compared with the header information in the subsequent synchronization signal to determine whether they match with each other, if the stream signal includes different kinds of sampling frequencies, there will be a frame(s) that cannot be reproduced.

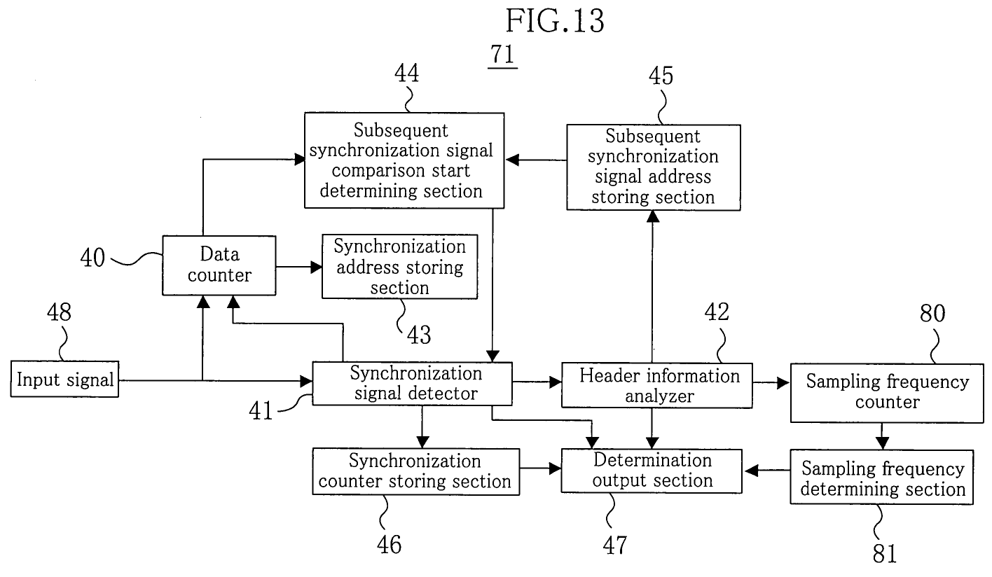

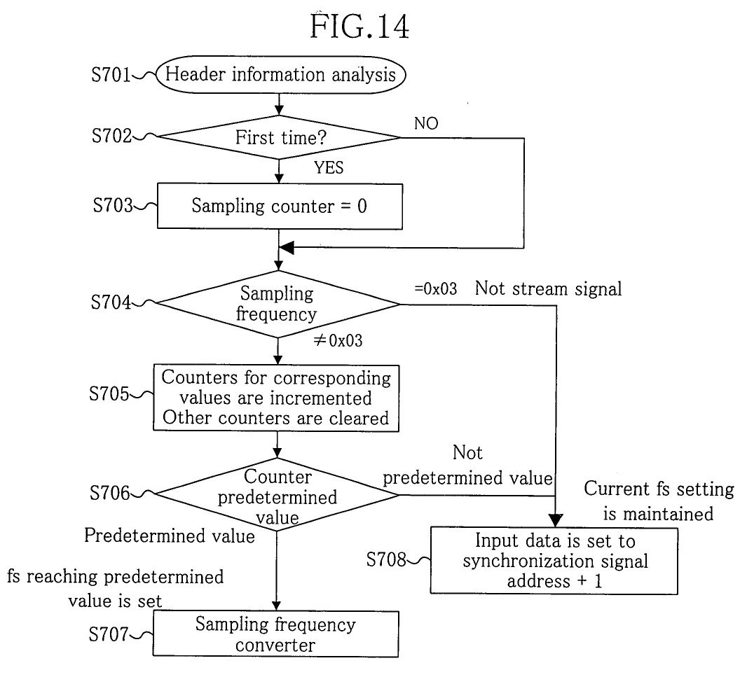

FIG. 13 illustrates the configuration of a synchronization signal detecting section 71, while FIG. 14 illustrates the flow of processing in the synchronization signal detecting section 71. In the second embodiment, the synchronization signal detecting section 71 includes a sampling frequency counter 80 for counting sampling information output from a header information analyzer 42 and a sampling frequency determining section 81 for instructing, based on values in the sampling counter, the sampling frequency converter 70 to initiate sampling frequency conversion.

Next, it will be described how the synchronization signal detecting section 71 operates with reference to FIG. 14. The synchronization signal detecting section 71 performs steps S701 through S708.

In a step S701, the header information analyzer 42 analyzes header information succeeding a synchronization signal to calculate a bit rate, while analyzing a sampling frequency and stores the analysis result.

In a step S702, it is determined whether or not the header information analysis has been performed for the first time. If the determination is “Yes”, the process branches to a step S703, in which the sample frequency counter is set to 0. If “No”, the process branches to a step S704.

In the step S704, if the sampling frequency has a value of “0x03”, it is determined that the input signal is not a stream signal and the process branches to a step S708. The sampling frequency has a value other than “0x03”, the process branches to a step S705.

In the step S705, counters for the kinds of sampling frequencies whose values correspond to counter values in the sampling frequency counter 80, which counts for each kind of sample frequency, are incremented, while counters for the other kinds of sampling frequencies that do not correspond are cleared.

In a step S706, if the counter values in the sampling frequency counter 80 reach predetermined values, the sampling frequency determining section 81 sets a sampling frequency and the sampling frequency converter 70 is operated in a step S707. If the counter values in the sampling frequency counter 80 do not reach the predetermined values, the process branches to the step S708, and the synchronization signal detection process is restarted from the address which is one bit ahead of the address stored in the synchronization address storing section 43, while the current sampling frequency setting is maintained.

It is then possible to reduce occurrence of noise caused by frequent switching resulting from a false-synchronization-signal induced malfunction.

### Third Embodiment

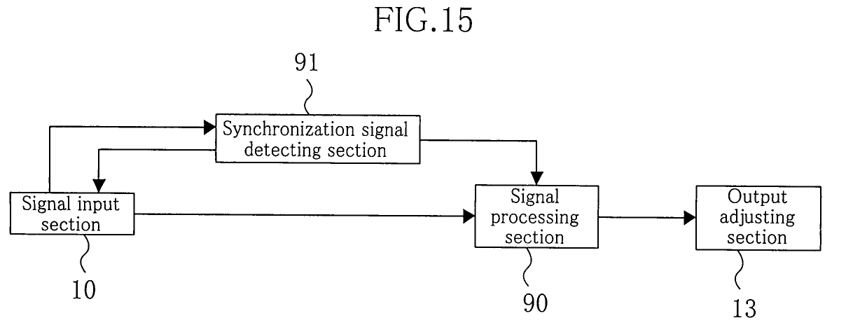

A third embodiment of the present invention will be described with reference to FIGS. 15 through 17. The configuration of, and the flow of processing in, a reproducing apparatus according to the third embodiment are basically the same as those of the first embodiment. The third embodiment will thus be described only in terms of its differences from the first embodiment.

As shown in FIG. 15, the reproducing apparatus is configured by incorporating in the reproducing apparatus of the first embodiment a signal processing section 90 capable of decoding one or more types of streams.

Based on layer information contained in an input stream signal, the signal processing section 90 determines a signal processing method which corresponds to the kind of stream to be decoded. In the reproducing apparatus with this configuration, if a malfunction occurs due to a false synchronization signal and false layer information succeeding the false synchronization signal to cause switching to take place frequently, noise may be produced.

In the first embodiment, the frames of the stream signal except for the frames whose stream type information is indeterminate are reproduced, thereby increasing the possibility that a false-synchronization-signal induced malfunction causes noise to occur. Also, in cases where the header information in the first synchronization signal is compared with the header information in the subsequent synchronization signal to determine whether they match with each other, if the stream signal includes different kinds of streams, there will be a frame(s) that cannot be reproduced.

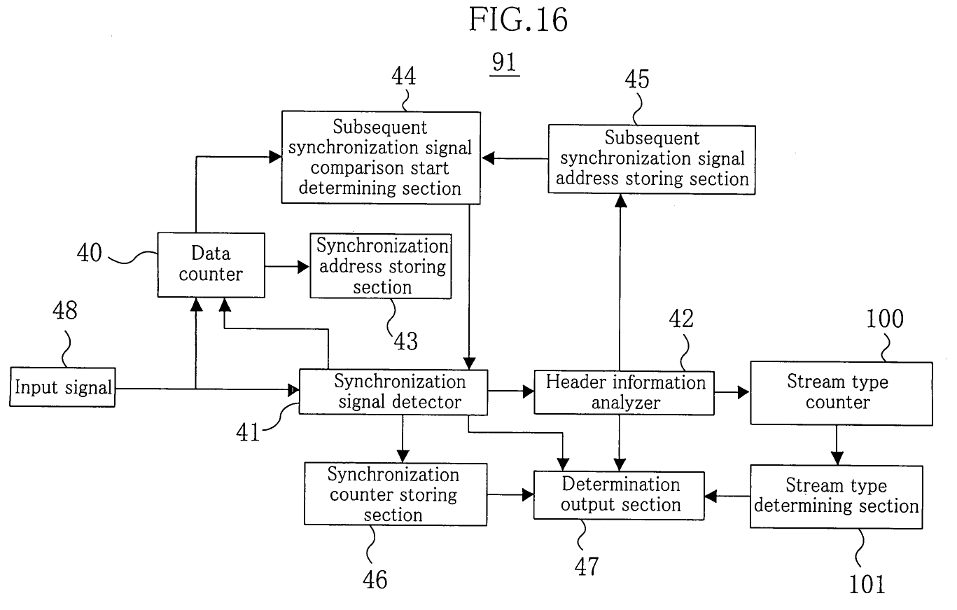

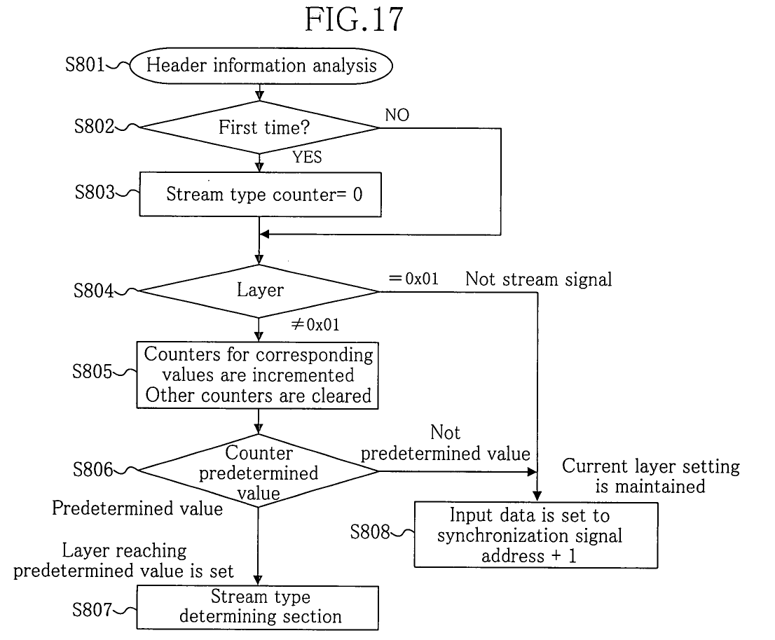

FIG. 16 illustrates the configuration of a synchronization signal detecting section 91, while FIG. 17 indicates the flow of processing in the synchronization signal detecting section 91. In the third embodiment of the present invention, the synchronization signal detecting section 91 is internally provided with a stream type counter 100 for counting information on stream type output from a header information analyzer 42 and a stream type determining section 101 for instructing the signal processing section 90 to initiate stream conversion based on values in the stream type counter 100.

Next, it will be described how the synchronization signal detecting section 91 operates with reference to FIG. 17. The synchronization signal detecting section 91 performs steps S801 through S808.

In a step S801, the header information analyzer 42 analyzes header information succeeding a synchronization signal to calculate a bit rate, while analyzing layer information and storing the result.

In a step S802, it is determined whether or not the header information analysis has been performed for the first time. If the determination is “Yes”, the process branches to a step S803, in which the stream type counter is set to 0. If “No”, the process branches to a step S804.

In the step S804, if the layer has a value of “0x01”, it is determined that the input signal is not a stream signal and the process branches to a step S808. If the layer has a value other than “0x01”, the process branches to a step S805.

In the step S805, counters for the kinds of streams whose values correspond to counter values in the stream type counter 100, which counts for each kind of stream, are incremented, while counters for the other kinds of streams that do not correspond are cleared.

In a step S806, if the counter values in the stream type counter 100 reach predetermined values, a layer is set, and the stream type determining section 101 is operated in a step S807. If the counter values in the stream type counter 100 do not reach the predetermined values, the process branches to the step S808, and the synchronization signal detection process is restarted from the address which is one bit ahead of the address stored in the synchronization address storing section 43, while the current layer setting is maintained.

It is then possible to reduce occurrence of noise caused by frequent layer switching resulting from a false-synchronization-signal induced malfunction.

### Fourth Embodiment

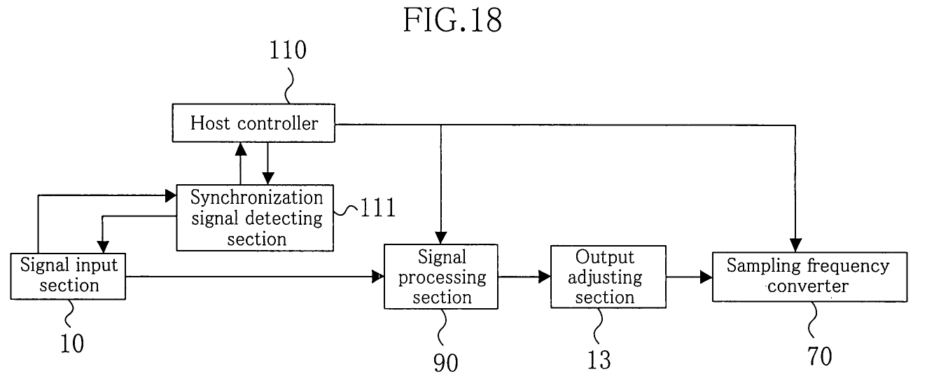

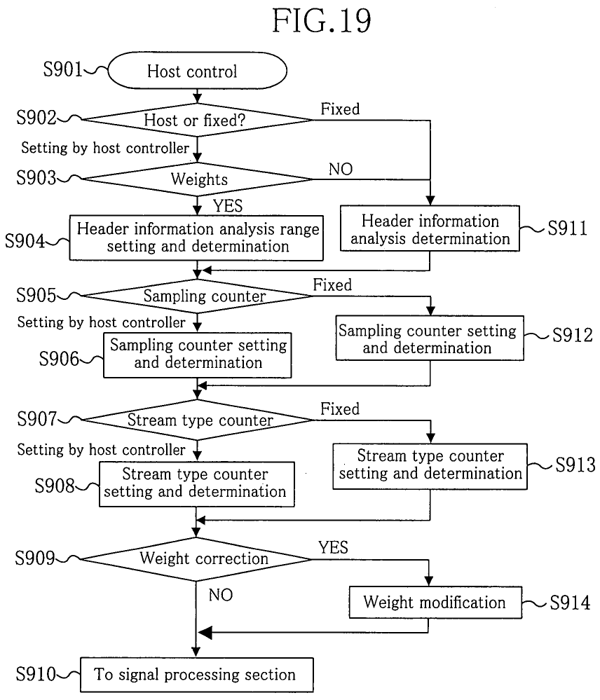

A fourth embodiment of the present invention will be described with reference to FIGS. 18 and 19. The configuration of, and the flow of processing in, a reproducing apparatus according to the fourth embodiment are basically the same as those of the first through third embodiments. The fourth embodiment will thus be described only in terms of its differences from the first through third embodiments.

As shown in FIG. 18, the reproducing apparatus is configured by incorporating a host controller 110 and a sampling frequency converter 70 in the reproducing apparatus of the third embodiment.

The host controller 110 establishes operation conditions for a synchronization signal detecting section 111, a signal processing section 90, and the sampling frequency converter 70 in accordance with the type of an input signal.

Next, it will be described how the synchronization signal detecting section 111 operates with reference to FIG. 19. The synchronization signal detecting section 111 performs steps S901 through S914.

In a step S901, the host controller 110 is operated. In a step S902, it is determined whether sets of information contained in header information are analyzed using fixed values or using arbitrary values set by the host controller 110. When the analysis is performed using the fixed values, the process branches to a step S911. When the analysis is performed using the arbitrary values set by the host controller 110, the process branches to a step S903.

In the step S903, it is determined whether or not weights are assigned to the sets of information in the header information. If the determination is “Yes”, the process branches to a step S904. If “No”, the process branches to the step S911.

In the step S904, the host controller 110 establishes the range of the analysis of the information sets in the header information and makes determinations. In the step S911, the information sets in the header information are analyzed and determinations are made using the fixed values.

In a step S905, it is determined whether sampling counters are set to fixed values, or set to arbitrary values set by the host controller 110. In the case of the fixed values, the process branches to a step S912. In the case where the host controller 110 sets the sampling counters, the process branches to a step S906.

In the step S906, the host controller 110 sets the sampling counters and makes determinations. In the step S912, the sampling counters are set and determinations are made using the fixed values.

In a step S907, it is determined whether stream type counters are set to fixed values, or set to arbitrary values set by the host controller 110. In the case of the fixed values, the process branches to a step S913. When the host controller 110 sets the sampling counters, the process branches to a step S908.

In the step S908, the host controller 110 establishes the stream type counter values and makes determinations using the established values. In the step S913, the stream type counters are set to the fixed values and determinations are made using those values.

In a step S909, it is determined whether or not to correct the weights assigned to the information sets in the header information. If “Yes”, the process branches to a step S914, in which the assigned weights are modified. If “No”, the process branches to a step S910 and output information is output to the signal processing section 90.

As describe above, the host controller 110, which controls the synchronization signal detecting section 111, assigns weights to the information sets in the header information, such that the stream type can be determined with high reliability, thereby reducing decode errors. Also, in determining, using fixed values or conditions specified by the host controller 110, whether a signal is a false synchronization signal or a synchronization signal, the synchronization signal detecting section 111 notifies the host controller 110 of the determination state. Therefore, the information on the weights, that is, the ranking, can be changed by the external controller 110 in any way according to the state of the stream, allowing the determination on the input signal to be made more accurately.

In addition, since the host controller 110 externally changes the target values in the stream type counter 100 to arbitrary values, determinations about the synchronization signals or the stream types can be made in accordance with the processing capability and the stream type.

If a host controller 110 is incorporated in the reproducing apparatus of the second embodiment, the host controller 110 externally changes the target values in the sampling frequency counter to arbitrary values, whereby determinations about sampling frequencies can be made in accordance with the processing capability and the stream type.

The present invention, capable of reducing occurrence of noise in reproducing an audio signal, is applicable to reproducing apparatuses capable of reproducing audio signals or the like.

1. A reproducing apparatus comprising:
a signal input section for receiving an input signal containing a PCM digital audio signal or a stream signal which is compression-coded at given bit rates and in which synchronization signals and frame headers are recorded at intervals defined by the bit rates, each synchronization signal indicating the beginning of a frame which is a unit for processing, each frame header indicating information on a corresponding one of the bit rates;
a synchronization signal detecting section for detecting the synchronization signals in the input signal, thereby determining a type of the input signal;
a host controller for setting an operation condition for the synchronization signal detecting section in accordance with the type of the input signal, and outputting output information which determines output;
a signal processing section for subjecting the input signal a signal processing process according to the output information; and
an output adjusting section for outputting data resulting from the signal processing process performed by the signal processing section.

2. The apparatus of claim 1, wherein the apparatus is configured to process a plurality of said input signals.

3. The apparatus of claim 1, wherein the synchronization signal detecting section includes:
a data counter for counting a data amount in the input signal to output an address in the input signal;
a synchronization signal detector for detecting one of the synchronization signals in the input signal and outputting a detection signal indicating a result of the detection;
a synchronization address storing section for storing, in response to the detection signal, an address which is output from the data counter and corresponds to the head of the detected synchronization signal;
a synchronization signal counter for counting in response to the detection signal when the synchronization signals are input successively;
a header information analyzer for calculating, in response to the detection signal, a bit rate from frame header information succeeding the detected synchronization signal and calculating an address interval to a subsequent synchronization signal;
a subsequent synchronization signal address storing section for calculating an address of the subsequent synchronization signal based on a result of the calculation performed by the header information analyzer and storing therein data on the address;
a synchronization signal comparison start determining section for outputting a determination of start of synchronization signal detection to the synchronization signal detector when a value in the data counter matches the address data stored in the subsequent synchronization signal address storing section; and
a determination outputting section for determining whether the input signal is the stream signal or the PCM digital audio signal based on a value in the synchronization signal counter and outputting information on the determination.

4. The apparatus of claim 3, further comprising a sampling frequency converter for converting an output signal produced from the output adjusting section to a predetermined sampling frequency.

5. The apparatus of claim 4, wherein the synchronization signal detecting section further includes:
a sampling counter for counting sampling information output from the header information analyzer, and
a sampling frequency determining section for instructing, based on a value in the sampling counter, the sampling frequency converter to initiate the sampling frequency conversion.

6. The apparatus of claim 3, wherein the synchronization signal detecting section further includes:
a stream type counter for counting stream type information output from the header information analyzer, and
a stream type determining section for instructing, based on a value in the stream type counter, the signal processing section to initiate stream conversion.

7. The apparatus of claim 1, wherein the host controller includes means for analyzing the frame header information and outputting results of the analysis, assigning weights to the analysis results, and reselecting, based on the assigned weights, information to be analyzed.

8. A method for controlling the reproducing apparatus of claim 1, comprising:
a step in which only part of an input signal is decoded;
a step in which a synchronization signal in the input signal is detected;
a step in which a location of a subsequent synchronization signal is calculated from frame header information succeeding the synchronization signal;
a step in which if the synchronization signal is present in the location of the subsequent synchronization signal, it is determined that the input signal is a stream signal;
a step in which if it has not been determined that the input signal is a stream signal, synchronization signal search is restarted from a location which is a given value ahead of the detected synchronization signal; and
a step in which after the synchronization signal search has been repeated, if the synchronization signal has not been detected from a predetermined search area, it is determined that the input signal is a PCM digital audio signal.

9. A method for controlling the reproducing apparatus of claim 5, comprising:
a step in which the sampling counter counts up the sampling information output from the header information analyzer until the count matches a predetermined target value,
a step in which if the value in the sampling counter matches the target value, it is determined that the sampling frequency is stabilized, and
a step in which the sampling frequency determining section provides the sampling frequency converter with the sampling information.

10. The method of claim 9, wherein the target value in the sampling counter is a value equal to or grater than 2, and
the target value is fixed or the host controller sets the target value to a given value.

11. A method for controlling the reproducing apparatus of claim 6, comprising:
a step in which the stream type counter counts up the stream type information output from the header information analyzer until the count matches a predetermined target value,
a step in which if the value in the stream type counter matches the target value, it is determined that the stream type is stabilized, and
a step in which the stream type determining section provides the signal processing section with the stream type information.

12. The method of claim 11, wherein the target value in the stream type counter is a value equal to or greater than 2, and
the target value is fixed or the host controller sets the target value to a given value.

13. The method of claim 8, wherein the host controller sets in arbitrary manners the number of bits by which the input signal is input, a to-be-input data area in the input signal, a restarting position of synchronization signal search in the input signal, and to-be-compared frame header information in the input signal.

14. The method of claim 13, wherein the input signal is input by one or more bits, and
the number of bits by which the input signal is input is fixed or the host controller sets the number of bits to a given value.

15. The method of claim 13, wherein the to-be-input data area in the input signal is data of one or more frames, and
the data area is fixed or the host controller sets the data area in an arbitrary way.

16. The method of claim 13, wherein the restarting position of synchronization signal search in the input signal is a position which is shifted from the detected synchronization signal by one or more bits, and
the search restarting position is fixed or the host controller sets the search restarting position to a given value.

17. The method of claim 13, wherein the to-be-compared frame header information in the input signal contains one or more sets of information, and
the frame header information is fixed or the host controller sets the frame header information in an arbitrary way.

18. The method of claim 13, wherein a determination condition for the to-be-compared frame header information in the input signal is based on counter information which is counted when first header information matches subsequent header information, and
the determination condition is fixed or the host controller sets the determination condition in an arbitrary way.
